(19) United States
(12) Patent Application Publication
(10) Pub. No.: US 2025/0183037 A1
(43) Pub. Date: Jun. 5, 2025

(54) METHODS FOR ENABLING CHEMICAL MECHANICAL POLISHING AND BONDING OF ALUMINUM-CONTAINING MATERIALS

(71) Applicant: Applied Materials, Inc., Santa Clara, CA (US)

(72) Inventors: Maria Gorchichko, San Jose, CA (US); Yoocharn Jeon, Palo Alto, CA (US); Siddarth Krishnan, San Jose, CA (US); Liang Song, San Jose, CA (US); Chengyu Liu, San Jose, CA (US); Meng Zhu, San Jose, CA (US); Kun Li, Delmar, NY (US); Jason A. Appell, Malta, NY (US); Veeraraghavan S. Basker, Fremont, CA (US); Benjamin D. Briggs, Merrimack, NH (US)

(73) Assignee: Applied Materials, Inc., Santa Clara, CA (US)

(21) Appl. No.: 18/958,271

(22) Filed: Nov. 25, 2024

Related U.S. Application Data
(60) Provisional application No. 63/604,543, filed on Nov. 30, 2023.

(51) Int. Cl. H01L 21/18; H01L 21/02; H01L 21/3105; H01L 21/321

(52) U.S. Cl. CPC H01L 21/185; H01L 21/31051; H01L 21/3212

(57) ABSTRACT

Exemplary semiconductor processing methods may include depositing a first material on a first substrate. The first material may be characterized by a first average surface roughness greater than 5 Å. The methods may include depositing a fill material on the first material. The methods may include planarizing the fill material to form a planarized fill material. The planarized fill material may be characterized by a second average surface roughness less than the first average surface roughness. The methods may include bonding the planarized fill material to a second substrate.

### CROSS-REFERENCE TO RELATED APPLICATIONS

This application claims the benefit of, and priority to U.S. Provisional Application Ser. No. 63/604,543, filed Nov. 30, 2023, which is hereby incorporated by reference in its entirety for all purposes.

### TECHNICAL FIELD

The present technology relates to semiconductor processing methods and chambers. More specifically, the present technology relates to methods of depositing materials, planarizing materials, and bonding materials.

### BACKGROUND

Integrated circuits are made possible by processes which produce intricately patterned material layers on substrate surfaces. Producing patterned material on a substrate requires controlled methods for forming and removing material. Material characteristics may affect how the device operates, and may also affect how the materials are removed relative to one another. Deposition may produce materials having certain characteristics, which may affect the assembly and/or performance of the device. The characteristics of the material may be adjusted or enhanced by modifying the deposition conditions, such as the chemistry of precursors provided during deposition and/or processing conditions during deposition, as well as through post-deposition operations.

Thus, there is a need for improved systems and methods that can be used to produce high quality devices and structures. These and other needs are addressed by the present technology.

### SUMMARY

Exemplary semiconductor processing methods may include depositing a first material on a first substrate. The first material may be characterized by a first average surface roughness greater than 5 Å. The methods may include depositing a fill material on the first material. The methods may include planarizing the fill material to form a planarized fill material. The planarized fill material may be characterized by a second average surface roughness less than the first average surface roughness. The methods may include bonding the planarized fill material to a second substrate.

In some embodiments, the first material may be or include an aluminum-containing material is a crystalline material. The aluminum-containing material may be a crystalline material. The first material may be or include aluminum nitride (AlN). The fill material may be or include a silicon-containing material or a metal-containing material. The fill material may be or include silicon oxide (SiO₂), silicon oxynitride (SiON), silicon carbide (SiC), or silicon carbonitride (SiCN). The fill material may be or include tantalum nitride (TaN), aluminum (Al), or aluminum oxide (Al₂O₃). The second average surface roughness may be less than 5 Å. Planarizing the fill material to form the planarized fill material may include performing a chemical mechanical polishing (CMP) process. An interface between the aluminum-containing material on the first substrate and the second substrate may be free of aluminum-and-oxygen-containing material.

Some embodiments of the present technology may encompass semiconductor processing methods. The methods may include providing an aluminum-containing precursor to a first processing region of a first semiconductor processing chamber. The methods may include depositing an aluminum-containing material on a first substrate. The aluminum-containing material may be characterized by a first average surface roughness. The methods may include providing one or more fill material precursors to a second processing region of a second semiconductor processing chamber. The methods may include depositing a fill material on the aluminum-containing material. The methods may include transferring the first substrate to a chemical mechanical polishing (CMP) system. The methods may include planarizing the fill material to form a planarized fill material. The planarized fill material may be characterized by a second average surface roughness less than the first average surface roughness.

In some embodiments, the methods may include providing a nitrogen-containing precursor to the first processing region of the first semiconductor processing chamber with the aluminum-containing precursor. The fill material precursors may be a silicon-containing precursor, an oxygen-containing precursor, a nitrogen-containing precursor, a carbon-containing precursor, a metal-containing precursor, or combinations thereof. The metal-containing precursor may be or include tantalum or aluminum. Planarizing the fill material to form the planarized fill material may include removing the fill material with the aluminum-containing material being a stop material. The methods may include bonding the planarized fill material to a second substrate. Bonding the planarized fill material to the second substrate may be performed without application of pressure.

Some embodiments of the present technology may encompass semiconductor processing methods. The methods may include providing an aluminum-containing precursor and a nitrogen-containing precursor to a first processing region of a first semiconductor processing chamber. The methods may include depositing an aluminum-and-nitrogen-containing material on a first substrate. The aluminum-and-nitrogen-containing material may be characterized by a first average surface roughness. The methods may include providing one or more fill material precursors to a second processing region of a second semiconductor processing chamber. The methods may include depositing a fill material on the aluminum-and-nitrogen-containing material. The methods may include transferring the first substrate to a chemical mechanical polishing (CMP) system. The methods may include planarizing the fill material to form a planarized fill material, wherein the planarized fill material is characterized by a second average surface roughness less than the first average surface roughness. The methods may include bonding the planarized fill material to a second substrate.

In some embodiments, the first average surface roughness may be greater than or about 20 Å. The second substrate may be or include a silicon-containing material.

Such technology may provide numerous benefits over conventional processing methods. For example, utilizing a fill material over aluminum-containing material may reduce the average surface roughness. The reduced average surface roughness may allow for bonding without the application of high temperature and/or high pressure. Additionally, the presence of a surface with reduced average surface roughness may allow for bonding to additional materials. These and other embodiments, along with many of their advantages and features, are described in more detail in conjunction with the below description and attached figures.

### BRIEF DESCRIPTION OF THE DRA WINGS

A further understanding of the nature and advantages of the disclosed technology may be realized by reference to the remaining portions of the specification and the drawings.

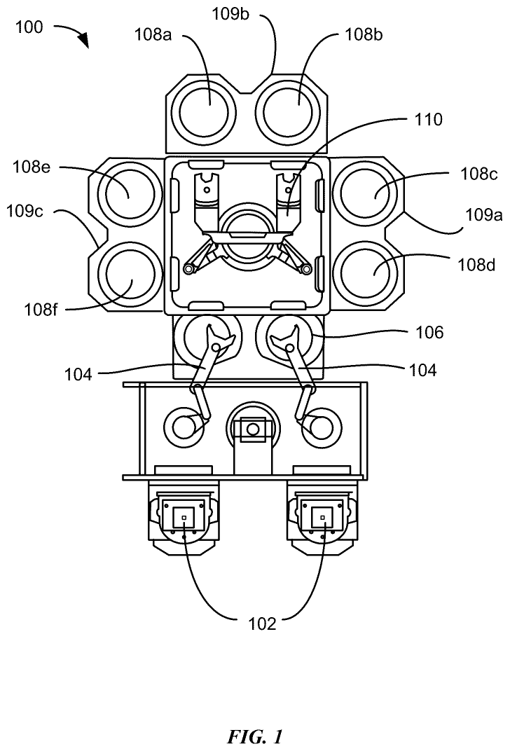

FIG. 1 shows a top plan view of an exemplary processing system according to some embodiments of the present technology.

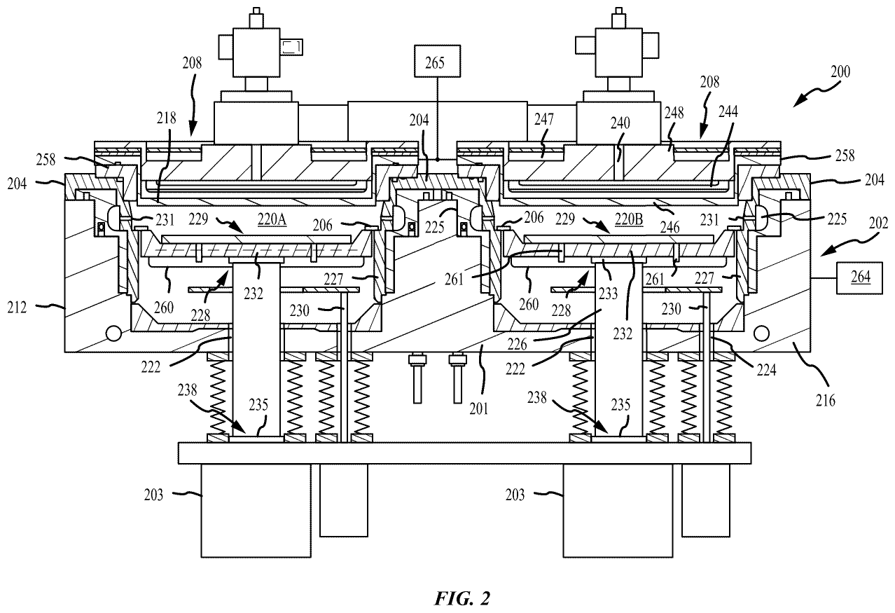

FIG. 2 shows a schematic cross-sectional view of an exemplary plasma system according to some embodiments of the present technology.

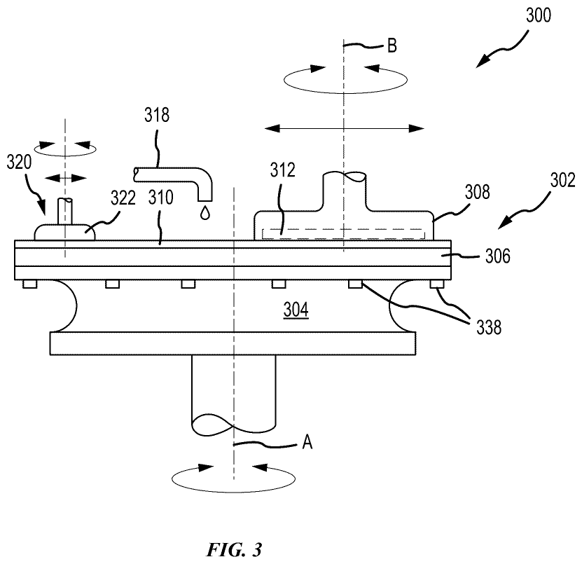

FIG. 3 shows a schematic cross-sectional view of an exemplary processing system according to some embodiments of the present technology.

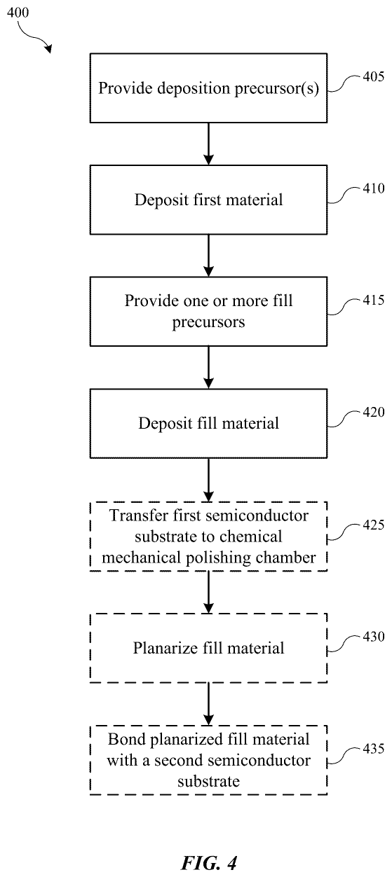

FIG. 4 shows operations of an exemplary method of semiconductor processing according to some embodiments of the present technology.

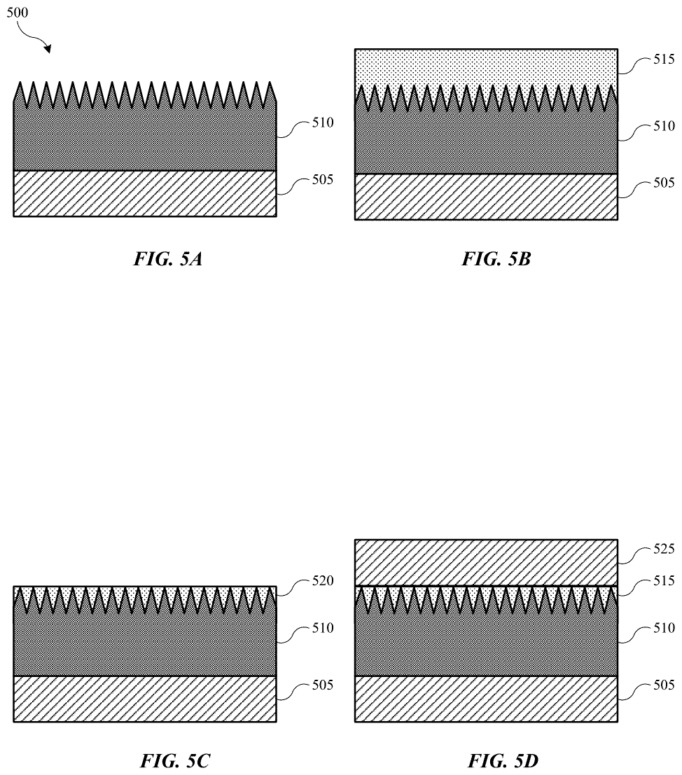

FIGS. 5A-D show exemplary schematic cross-sectional views of structures in which material layers are included and processed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

During semiconductor processing, material layers may be formed on a substrate. After a number of material layers are formed on the substrate, the substrate may be bonded to a second substrate such as for packaging applications. Due to extremely high thermal conductivity, dielectric properties, and similar thermal stress properties to silicon, aluminum nitride (AlN) may be a promising material for heat dissipation in packaging applications. Most packaging applications utilize bonding of heat dissipation material to facilitate cooling of the device. However, successful bonding typically requires low average surface roughness of the material. While AlN, for example, may have desirable thermal conductivity, dielectric properties, and thermal stress properties, the average surface roughness may not be suitable for bonding to another material. More specifically, AlN may be a hard, highly crystalline film with large vertically oriented grains. Achieving low roughness of AlN via a chemical mechanical polishing (CMP) process may be extremely hard and may detrimentally impact subsequent bonding attempts. One approach to bond rough AlN may be thermocompression, but this bonding method may only be applicable to bonding to another AlN material layer at high temperatures and/or high pressures.

The present technology may overcome these issues by reducing an average surface roughness of the material layer, such as the AlN material layer. By performing a deposition of a fill material, followed by a planarization, such as a CMP process, of the fill material, a much smoother surface may be provided. The smoothed surface may be suitable for bonding to other materials, not only another AlN material layer, and may be suitable for bonding without the use of high temperature and/or high pressure. As such, the bonding may be referred to as fusion bonding. Furthermore, the bonding may be performed without formation of an interface layer between the two structures to be bonded.

Although the remaining disclosure will routinely identify specific deposition, planarization, and bonding processes utilizing the disclosed technology, it will be readily understood that the systems and methods are equally applicable to other chambers, as well as processes as may occur in the described chambers. Accordingly, the technology should not be considered to be so limited as for use with these specific processes or chambers alone. The disclosure will discuss one possible system and chambers that may be used to perform deposition and planarizing processes according to embodiments of the present technology before additional details according to embodiments of the present technology are described.

FIG. 1 shows a top plan view of one embodiment of a processing system 100 of deposition, etching, baking, and UV treatment chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including plasma-enhanced chemical vapor deposition, atomic layer deposition, physical vapor deposition, etch, UV treatments, pre-clean, degas, orientation, and other substrate processes including, annealing, ashing, etc.

The substrate processing chambers 108a-f may include one or more system components for depositing, annealing, UV treating and/or etching a dielectric or other material on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric materials on the substrate. Any one or more of the processes described may be carried out in chambers separated from the fabrication system shown in different embodiments. It will be appreciated that additional configurations of deposition, etching, annealing, and UV treatment chambers for dielectric materials are contemplated by system 100.

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include lid stack components according to embodiments of the present technology, and as may be explained further below. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a dual-channel showerhead 218 into the processing region 220B. The dual-channel showerhead 218 may include an annular base plate 248 having a blocker plate 244 disposed intermediate to a faceplate 246. A radio frequency (“RF”) source 265 may be coupled with the dual-channel showerhead 218, which may power the dual-channel showerhead 218 to facilitate generating a plasma region between the faceplate 246 of the dual-channel showerhead 218 and the pedestal 228. The dual-channel showerhead 218 and/or faceplate 246 may include one or more openings to permit the flow of precursors from the precursor distribution system 208 to the processing regions 220A and/or 220B. In some embodiments, the openings may include at least one of straight-shaped openings and conical-shaped openings. In some embodiments, the RF source may be coupled with other portions of the chamber body 202, such as the pedestal 228, to facilitate plasma generation. A dielectric isolator 258 may be disposed between the lid 204 and the dual-channel showerhead 218 to prevent conducting RF power to the lid 204. A shadow ring 206 may be disposed on the periphery of the pedestal 228 that engages the pedestal 228.

An optional cooling channel 247 may be formed in the annular base plate 248 of the precursor distribution system 208 to cool the annular base plate 248 during operation. A heat transfer fluid, such as water, ethylene glycol, a gas, or the like, may be circulated through the cooling channel 247 such that the base plate 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

FIG. 3 shows a schematic cross-sectional view of an exemplary polishing system 300 according to some embodiments of the present technology. Polishing system 300 includes a platen assembly 302, which includes a lower platen 304 and an upper platen 306. Lower platen 304 may define an interior volume or cavity through which connections can be made, as well as in which may be included end-point detection equipment or other sensors or devices, such as eddy current sensors, optical sensors, or other components for monitoring polishing operations or components. For example, and as described further below, fluid couplings may be formed with lines extending through the lower platen 304, and which may access upper platen 306 through a backside of the upper platen. Platen assembly 302 may include a polishing pad 310 mounted on a first surface of the upper platen. A substrate carrier 308, or carrier head, may be disposed above the polishing pad 310 and may face the polishing pad 310. The platen assembly 302 may be rotatable about an axis A, while the substrate carrier 308 may be rotatable about an axis B. The substrate carrier may also be configured to sweep back and forth from an inner radius to an outer radius along the platen assembly, which may, in part, reduce uneven wear of the surface of the polishing pad 310. The polishing system 300 may also include a fluid delivery arm 318 positioned above the polishing pad 310, and which may be used to deliver polishing fluids, such as a polishing slurry, onto the polishing pad 310. Additionally, a pad conditioning assembly 320 may be disposed above the polishing pad 310, and may face the polishing pad 310.

In some embodiments of performing a chemical-mechanical polishing process, the rotating and/or sweeping substrate carrier 308 may exert a downforce against a substrate 312, which is shown in phantom and may be disposed within or coupled with the substrate carrier. The downward force applied may depress a material surface of the substrate 312 against the polishing pad 310 as the polishing pad 310 rotates about a central axis of the platen assembly. The interaction of the substrate 312 against the polishing pad 310 may occur in the presence of one or more polishing fluids delivered by the fluid delivery arm 318. A typical polishing fluid may include a slurry formed of an aqueous solution in which abrasive particles may be suspended. Often, the polishing fluid contains a pH adjuster and other chemically active components, such as an oxidizing agent, which may enable chemical mechanical polishing of the material surface of the substrate 312.

The pad conditioning assembly 320 may be operated to apply a fixed abrasive conditioning disk 322 against the surface of the polishing pad 310, which may be rotated as previously noted. The conditioning disk may be operated against the pad prior to, subsequent, or during polishing of the substrate 312. Conditioning the polishing pad 310 with the conditioning disk 322 may maintain the polishing pad 310 in a desired condition by abrading, rejuvenating, and removing polish byproducts and other debris from the polishing surface of the polishing pad 310. Upper platen 306 may be disposed on a mounting surface of the lower platen 304, and may be coupled with the lower platen 304 using a plurality of fasteners 338, such as extending through an annular flange shaped portion of the lower platen 304.

The polishing platen assembly 302, and thus the upper platen 306, may be suitably sized for any desired polishing system, and may be sized for a substrate of any diameter, including 200 mm, 300 mm, 450 mm, or greater. For example, a polishing platen assembly configured to polish 300 mm diameter substrates, may be characterized by a diameter of more than about 300 mm, such as between about 500 mm and about 1000 mm, or more than about 500 mm. The platen may be adjusted in diameter to accommodate substrates characterized by a larger or smaller diameter, or for a polishing platen 306 sized for concurrent polishing of multiple substrates. The upper platen 306 may be characterized by a thickness of between about 20 mm and about 150 mm, and may be characterized by a thickness of less than or about 100 mm, such as less than or about 80 mm, less than or about 60 mm, less than or about 40 mm, or less. In some embodiments, a ratio of a diameter to a thickness of the polishing platen 306 may be greater than or about 3:1, greater than or about 5:1, greater than or about 10:1, greater than or about 15:1, greater than or about 20:1, greater than or about 25:1, greater than or about 30:1, greater than or about 40:1, greater than or about 50:1, or more.

The upper platen and/or the lower platen may be formed of a suitably rigid, light-weight, and polishing fluid corrosion-resistant material, such as aluminum, an aluminum alloy, or stainless steel, although any number of materials may be used. Polishing pad 310 may be formed of any number of materials, including polymeric materials, such as polyurethane, a polycarbonate, fluoropolymers, polytetrafluoroethylene polyphenylene sulfide, or combinations of any of these or other materials. Additional materials may be or include open or closed cell foamed polymers, elastomers, felt, impregnated felt, plastics, or any other materials that may be compatible with the processing chemistries. It is to be understood that polishing system 300 is included to provide suitable reference to components discussed below, which may be incorporated in system 100, although the description of polishing system 300 is not intended to limit the present technology in any way, as embodiments of the present technology may be incorporated in any number of polishing systems that may benefit from the components and/or capabilities as described further below.

FIG. 4 shows operations of an exemplary method 300 of semiconductor processing according to some embodiments of the present technology. The method may be performed in a variety of processing chambers, including systems 100, 200, and/or 300 described above, as well as any other chamber in which deposition, planarizing, and bonding operations may be performed. Method 400 may include a number of optional operations, which may or may not be specifically associated with some embodiments of methods according to the present technology. Method 400 may describe operations shown schematically in FIGS. 5A-5D, the illustrations of which will be described in conjunction with the operations of method 400. It is to be understood that the figures illustrate only partial schematic views, and a substrate 505 may contain any number of additional materials and features having a variety of characteristics and aspects as illustrated in the figures.

Method 400 may or may not involve optional operations to develop the semiconductor structure to a particular semiconductor processing method, such as one or more operations of the method 400. It is to be understood that method 400 may be performed on any number of semiconductor structures or substrates 505, as illustrated in FIG. 5A, including exemplary structure 500 on which a first material 510, such as an aluminum-containing material, may be formed, a fill material 515 may be formed, and subsequent bonding to a second substrate 505 may be performed. Although the following description will regularly discuss aluminum-containing materials, such as aluminum nitride, it is to be understood that any number of materials may be used in embodiments of the present technology, and the present technology should not be limited to any particular material in which average surface roughness of a deposited material may be reduced. For example, the first material 510, in addition to an aluminum-containing material (such as aluminum nitride), may be or include, but is not limited to, a carbon-containing material (such as diamond), a gallium-containing material (such as gallium nitride), a boron-containing material (such as boron nitride), or any other material with an average surface roughness that would be too rough for fusion bonding or direct bonding. In embodiments, materials with an average surface roughness of greater than 5 Å may be too rough for fusion bonding or direct bonding. In embodiments, the increased average surface roughness of the first material 510 may be resultant from a multi-crystalline material, as opposed to a single crystalline or non-crystalline material, which may comparatively be characterized by a reduced average surface roughness.

In some embodiments, method 400 may include providing a deposition precursor, such as an aluminum-containing precursor, to a processing region of a semiconductor processing chamber, such as processing region 220A or 220B. A substrate, such as substrate 505, may be housed in the processing region of the semiconductor processing chamber as the deposition precursors are provided into the chamber. In some embodiments, a secondary precursor, such as a nitrogen-containing precursor, may be provided to the processing region of the semiconductor processing chamber with the deposition precursor. One or more carrier gases, such as helium, argon, and nitrogen, may be provided with the deposition precursor and, if present, the secondary precursor. Although the one or more carrier gases may be delivered with other precursors, the carrier gases may be considered inert gases that do not react to form part of the as-deposited material. The one or more carrier gases may be delivered with other deposition precursors to serve as a diluent or assist with distribution.

In embodiments, plasma effluents of the deposition precursor and, if present, the secondary precursor and/or carrier gases may be formed. However, it is also contemplated that plasma effluents may not be formed, and a thermal deposition instead may result. At operation 410 and as illustrated in FIG. 5A, method 400 may include depositing the first material 510 on the substrate 505. In embodiments, the first material 510 may be an aluminum-containing material, such as an aluminum-and-nitrogen-containing material (e.g., aluminum nitride (AlN)). The first material 510 may be a crystalline material, such as a multi-crystalline material, as opposed to a single crystalline or non-crystalline material.

The first material 510 may be characterized by a first average surface roughness. In embodiments, the first average surface roughness may be greater than or about 5 Å, and may be greater than or about 6 Å, greater than or about 7 Å, greater than or about 8 Å, greater than or about 9 Å, greater than or about 10 Å, greater than or about 12 Å, greater than or about 14 Å, greater than or about 15 Å, greater than or about 16 Å, greater than or about 18 Å, greater than or about 20 Å, greater than or about 30 Å, greater than or about 40 Å, greater than or about 50 Å, greater than or about 60 Å, greater than or about 70 Å, greater than or about 80 Å, greater than or about 90 Å, greater than or about 100 Å, or more. This average surface roughness, which may be attributed to the crystallinity of the material, may require high temperature and/or high pressure to bond the first material 510 to other similar materials, such as another aluminum-containing material in a packaging application when the first material 510 is an aluminum-containing material. Additionally, this average surface roughness may result in difficulty in bonding the first material 510 to dissimilar materials, such as in a packaging application. Accordingly, the present technology may target a reduction to the average surface roughness of the first material 510 to allow subsequent bonding to similar or dissimilar materials without application of high temperature and/or high pressure.

At operation 415, method 400 may include providing one or more fill material precursors to a processing region of a semiconductor processing chamber. In embodiments, the one or more fill material precursors may be provided to a same processing region of a processing chamber in which the first material 510 was deposited. Alternatively, the substrate 505 may be transferred, and the one or more fill material precursors may be provided to a second processing region of a second processing chamber. The fill material precursors may be or include a silicon-containing precursor, an oxygen-containing precursor, a nitrogen-containing precursor, a carbon-containing precursor, a metal-containing precursor, or combinations thereof. In embodiments, the metal-containing precursor may include tantalum, titanium, copper, or aluminum, for example.

Similar to the deposition of the first material 510, plasma effluents of the one or more fill material precursors and/or carrier gases may be formed. However, it is also contemplated that plasma effluents may not be formed, and a thermal deposition instead may result. As illustrated in FIG. 5B, method 400 may include depositing a fill material 515 on the first material 510 at operation 420. Depending on the fill material precursors provided at operation 415, the fill material may be or include a silicon-containing material or a metal-containing material. Exemplary silicon-containing materials may be or include silicon oxide (SiO₂), silicon oxynitride (SiON), silicon carbide (SiC), or silicon carbonitride (SiCN). Exemplary metal-containing materials may be or include tantalum nitride (TaN), titanium nitride (TiN), copper (Cu), aluminum (Al), or aluminum oxide (Al₂O₃). The fill material 515 may be deposited on the first material 510 to at least partially or even fully cover the first material 510.

At optional operation 425, method 400 may include transferring the substrate 505 to a chemical mechanical polishing (CMP) system, such as system 300. At optional operation 430 and as illustrated in FIG. 5C, method 400 may include planarizing the fill material 515 to form a planarized fill material 520. The planarizing may remove a portion of the fill material 515 to form the planarized fill material 520. The planarized fill material 520 may be characterized by a second average surface roughness less than the first average surface roughness. In embodiments, the second average surface roughness may be less than or about 100 Å, and may be less than or about 90 Å, less than or about 80 Å, less than or about 70 Å, greater than or about 60 Å, less than or about 50 Å, less than or about 40 Å, less than or about 30 Å, less than or about 10 Å, less than or about 10 Å, less than or about 5 Å, or less. The reduced average surface roughness may allow for subsequent bonding, as further discussed below, to other materials such as a second substrate through various bonding methods such as fusion bonding.

Planarizing the fill material 515 to form the planarized fill material 520 may include removing the fill material 515 with the first material 510 being a stop material. As such, the planarization of the fill material 515 may expose at least a portion of the first material 510. However, it is also contemplated that the planarizing may not expose the first material 510. Any polishing operations, as one skilled in the art would appreciate, may be used to planarize the fill material 515 at optional operation 430.

As illustrated in FIG. 5D, method 400 may include bonding the planarized fill material 520 and/or exposed first material 510 on the substrate 505 to a second substrate 525 at optional operation 435. The second substrate 525 may be or include a silicon-containing material, such as silicon or silicon oxide (SiO). In embodiments, the bonding may occur via fusion bonding. Fusion bonding may refer to spontaneous adhesion of two planar surfaces without the addition of any intermediate layer. Accordingly, an interface between the first material 510 and/or the planarized fill material 520 on the substrate 505 and the second substrate 525 may be free of aluminum-and-oxygen-containing material. Additionally, in utilizing fusion bonding, no compression may be applied between the substrate 505 and the second substrate 525. As such, it may be necessary to reduce the average surface roughness of the first material 510 to ensure adequate bonding between the substrate 505 to the second substrate 525. Any fusion bonding operations, as one skilled in the art would appreciate, may be used to join the substrate 505 to the second substrate 525 at optional operation 435.

During any operation(s) of method 400, the substrate 505 may be characterized by a relatively low temperature. The processing region(s) and, therefore, the substrate 505 may be characterized by a temperature of, for example, less than or about 700° C., less than or about 650° C., less than or about 600° C., less than or about 550° C., less than or about 500° C., less than or about 450° C., less than or about 400° C., less than or about 350° C., less than or about 300° C., less than or about 250° C., less than or about 200° C., less than or about 150° C., less than or about 100° C., or less. Each of the operations of method 400 may be performed at a constant temperature, although it is contemplated that temperature may be adjusted throughout method 400. For example, providing the deposition precursor(s) and the resultant deposition at operations 405-410 may be performed at a first temperature. Providing the fill precursor(s) and the resultant deposition at operations 415-420 may be performed at a temperature similar to or the same as the first temperature. It is also contemplated that the temperature may be reduced to a second temperature prior to operations 415-435 of method 400, or operations 425-435 of method 400. In embodiments, the first temperature may be greater than or about 700° C., and may be greater than or about 800° C., greater than or about 900° C., greater than or about 1,000° C., greater than or about 1,100° C., or more. The second temperature may be any of the previously discussed temperatures, which may be selected based on a thermal budget.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a material” includes a plurality of such material, and reference to “the precursor” includes reference to one or more precursors and equivalents thereof known to those skilled in the art, and so forth. “About” and/or “approximately” as used herein when referring to a measurable value such as an amount, a temporal duration, and the like, encompasses variations of ±20% or ±10%, ±5%, or ±0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, +5%, or +0.1% from the specified value, as such variations are appropriate to in the context of the systems, devices, circuits, methods, and other implementations described herein.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
depositing a first material on a first substrate, wherein the first material is characterized by a first average surface roughness greater than 5 Å;
depositing a fill material on the first material;
planarizing the fill material to form a planarized fill material, wherein the planarized fill material is characterized by a second average surface roughness less than the first average surface roughness; and
bonding the planarized fill material to a second substrate.

2. The semiconductor processing method of claim 1, wherein the first material comprises an aluminum-containing material is a crystalline material.

3. The semiconductor processing method of claim 2, wherein the aluminum-containing material is a crystalline material.

4. The semiconductor processing method of claim 1, wherein the first material comprises aluminum nitride (AlN).

5. The semiconductor processing method of claim 1, wherein the fill material comprises a silicon-containing material or a metal-containing material.

6. The semiconductor processing method of claim 1, wherein the fill material comprises silicon oxide (SiO₂), silicon oxynitride (SiON), silicon carbide (SiC), or silicon carbonitride (SiCN).

7. The semiconductor processing method of claim 1, wherein the fill material comprises tantalum nitride (TaN), aluminum (Al), or aluminum oxide (Al₂O₃).

8. The semiconductor processing method of claim 1, wherein the second average surface roughness is less than 5 Å.

9. The semiconductor processing method of claim 1, wherein planarizing the fill material to form the planarized fill material comprises performing a chemical mechanical polishing (CMP) process.

10. The semiconductor processing method of claim 1, wherein an interface between the first material on the first substrate and the second substrate is free of aluminum-and-oxygen-containing material.

11. A semiconductor processing method comprising:
providing an aluminum-containing precursor to a first processing region of a first semiconductor processing chamber;
depositing an aluminum-containing material on a first substrate, wherein the aluminum-containing material is characterized by a first average surface roughness;
providing one or more fill material precursors to a second processing region of a second semiconductor processing chamber;
depositing a fill material on the aluminum-containing material;
transferring the first substrate to a chemical mechanical polishing (CMP) system; and
planarizing the fill material to form a planarized fill material, wherein the planarized fill material is characterized by a second average surface roughness less than the first average surface roughness.

12. The semiconductor processing method of claim 11, further comprising:
providing a nitrogen-containing precursor to the first processing region of the first semiconductor processing chamber with the aluminum-containing precursor.

13. The semiconductor processing method of claim 11, wherein the fill material precursors comprise a silicon-containing precursor, an oxygen-containing precursor, a nitrogen-containing precursor, a carbon-containing precursor, a metal-containing precursor, or combinations thereof.

14. The semiconductor processing method of claim 13, wherein the metal-containing precursor comprises tantalum or aluminum.

15. The semiconductor processing method of claim 11, wherein planarizing the fill material to form the planarized fill material comprises removing the fill material with the aluminum-containing material being a stop material.

16. The semiconductor processing method of claim 11, further comprising:
bonding the planarized fill material to a second substrate.

17. The semiconductor processing method of claim 16, wherein bonding the planarized fill material to the second substrate is performed without application of pressure.

18. A semiconductor processing method comprising:
providing an aluminum-containing precursor and a nitrogen-containing precursor to a first processing region of a first semiconductor processing chamber;
depositing an aluminum-and-nitrogen-containing material on a first substrate, wherein the aluminum-and-nitrogen-containing material is characterized by a first average surface roughness;
providing one or more fill material precursors to a second processing region of a second semiconductor processing chamber;
depositing a fill material on the aluminum-and-nitrogen-containing material;
transferring the first substrate to a chemical mechanical polishing (CMP) system;
planarizing the fill material to form a planarized fill material, wherein the planarized fill material is characterized by a second average surface roughness less than the first average surface roughness; and
bonding the planarized fill material to a second substrate.

19. The semiconductor processing method of claim 18, wherein the first average surface roughness is greater than or about 20 Å.

20. The semiconductor processing method of claim 18, wherein the second substrate comprises a silicon-containing material.
